(19) United States
(12) Patent Application Publication
(10) Pub. No.: US 2026/0361074 A1
(43) Pub. Date: Nov. 12, 2026

(54) CABLE CONTROL SYSTEM

(71) Applicants: CSG POWER GENERATION CO., LTD. MAINTENANCE AND TEST COMPANY, Guangzhou (CN); GUANGZHOU QIMING SHUZHI ENERGY TECHNOLOGY CO., LTD., Guangzhou (CN)

(72) Inventors: Wenbin YAN, Guangzhou (CN); Yu GONG, Guangzhou (CN); Guancheng QUAN, Guangzhou (CN); Yongqi LI, Guangzhou (CN); Qing LI, Guangzhou (CN); Minggang ZHU, Guangzhou (CN); Hang NIE, Guangzhou (CN); Qiang CHEN, Guangzhou (CN); Dehua LI, Guangzhou (CN); Lei ZHANG, Guangzhou (CN); Xiaohui HUANG, Guangzhou (CN); Chuangjia CHEN, Guangzhou (CN); Junjie DONG, Guangzhou (CN); Yao JIN, Guangzhou (CN); Xiaoliang LI, Guangzhou (CN); Xiao LIANG, Guangzhou (CN); Peng WANG, Guangzhou (CN); Peng LING, Guangzhou (CN); Jun JIANG, Guangzhou (CN); Xiangwei HUANG, Guangzhou (CN); Sijie WANG, Guangzhou (CN)

(73) Assignees: CSG POWER GENERATION CO., LTD. MAINTENANCE AND TEST COMPANY, Guangzhou (CN); GUANGZHOU QIMING SHUZHI ENERGY TECHNOLOGY CO., LTD., Guangzhou (CN)

(21) Appl. No.: 19/489,515

(22) PCT Filed: Dec. 16, 2024
(86) PCT No.: PCT/CN2024/139513

§ 371 Date: Dec. 2, 2025

(30) Foreign Application Priority Data
Mar. 11, 2024 (CN) 202410273467.7

(51) Int. Cl. H02H 7/22; G01K 1/024; G01K 3/00; G01R 31/58; H02B 1/30; H02H 1/00

(52) U.S. Cl. CPC H02H 7/22; G01K 1/024; G01K 3/005; G01R 31/58; H02B 1/305; H02H 1/0007

(57) ABSTRACT

A cable control system is provided, including a cable cabinet, a processor arranged in the cable cabinet, and a universal serial bus interface arranged outside the cable cabinet and connected to the processor. Cable ports of multiple cable circuits are further arranged outside the cable cabinet. Cable ports of each cable circuit include current signal input ports and current signal output ports of multiple cables. Current signal input port and current signal output port of each cable are connected via connection module arranged in the cable cabinet; the connection module is further connected to the processor; the processor is used for receiving, through the universal serial bus interface, cable control instruction transmitted in a wired transmission mode by a terminal, and controlling, according to the cable control instruction, the connection module for target cable corresponding to the cable control instruction, to control on/off of the target cable.

### CROSS-REFERENCE TO RELATED APPLICATIONS

This application is a U.S. National Stage Application, filed under 35 U.S.C. 371, of International Patent Application No. PCT/CN 2024/139513, filed on Dec. 16, 2024, which claims priority to Chinese Patent Application No. 202410273467.7, filed on Mar. 11, 2024, the entire contents of which are incorporated herein by reference.

### TECHNICAL FIELD

The present disclosure relates to the technical field of power grids, and in particular, to a cable control system.

### BACKGROUND

In power grid enterprises, control over cables is of extreme importance to ensure the quality of power supply of the power grid enterprises.

In the conventional art, when conducting control over a cable, manual operation is required on a terminal block connecting an end under test and a control end. However, this mode is prone to misoperation, missed operations, and improper operations, which may lead to hazardous situations and result in lower cable control safety.

### SUMMARY

Based on this, there is a need to provide, with respect to the above technical problems, a cable control system that can improve cable control safety.

The present disclosure provides a cable control system, including: a cable cabinet, a processor arranged inside the cable cabinet, and a universal serial bus interface that is arranged outside the cable cabinet and connected to the processor; where

cable ports of multiple cable circuits are further arranged outside the cable cabinet, the cable ports of each cable circuit include current signal input ports and current signal output ports of multiple cables, and the current signal input port and the current signal output port of each cable are connected via a connection module arranged inside the cable cabinet, the connection module being further connected to the processor;

the processor is configured for receiving, via the universal serial bus interface, a cable control instruction transmitted in a wired transmission mode by a terminal, and controlling, according to the cable control instruction, the connection module for a target cable corresponding to the cable control instruction, to control on/off of the target cable.

In an embodiment, the system further includes a communication module connected to the processor;

the communication module is configured for receiving the cable control instruction transmitted in the wireless transmission mode by the terminal, and sending the cable control instruction to the processor.

In an embodiment, the communication module is further configured for receiving an on/off state of each cable in each cable circuit acquired by the processor, and transmitting the on/off state of each cable in each cable circuit to the terminal, to enable the terminal to display the on/off state of each cable in each cable circuit.

In an embodiment, the system further includes a temperature detection module and an alarm module that are connected to the processor;

the temperature detection module is configured for detecting a temperature of each cable in a same cable circuit and sending the temperature of each cable in the same cable circuit to the processor; and

the processor is further configured for confirming, in a case where differences between the temperature of a cable and the temperatures of other cables in the same cable circuit are greater than a preset threshold, that the cable has a fault, triggering the alarm module to alarm, and sending fault information of the cable to the terminal through the communication module.

In an embodiment, the system further includes a current detection module connected to the processor;

the current detection module is configured for detecting current information at two ends of each cable in a same cable circuit and sending the current information at the two ends of each cable in the same cable circuit to the processor; and

the processor is further configured for sending, through the communication module, the current information at the two ends of each cable in the same cable circuit to the terminal.

In an embodiment, the system further includes a fault detection module connected to the processor;

the fault detection module is configured for detecting whether each cable in each cable circuit has a fault, and sending a fault state of each cable in each cable circuit to the processor; and

the processor is further configured for sending, through the communication module, the fault state of each cable in each cable circuit to the terminal.

In an embodiment, the system further includes an identity authentication module which is connected to each of the universal serial bus interface, the communication module, and the processor;

the identity authentication module is configured for verifying identity information carried in the cable control instruction received through the universal serial bus interface or through the communication module, and sending the cable control instruction to the processor in a case where the identity information passes verification.

In an embodiment, a corresponding cable indicator light is arranged near the current signal input port or the current signal output port of each cable, the cable indicator light being configured for indicating an on/off state and a fault state of the corresponding cable.

In an embodiment, a processor indicator light corresponding to the processor is further arranged outside the cable cabinet, the processor indicator light being configured for indicating a power supply state, an operating state, and a fault state of the processor.

In an embodiment, the system further includes a power supply module connected to the processor;

the power supply module is configured for supplying power to the processor.

According to the above cable control system, the system is provided with a cable cabinet, a processor arranged inside the cable cabinet, and a universal serial bus interface that is arranged outside the cable cabinet and connected to the processor. Cable ports of multiple cable circuits are further arranged outside the cable cabinet. Cable ports of each cable circuit include current signal input ports and current signal output ports of multiple cables, and the current signal input port and the current signal output port of each cable are connected via a connection module arranged inside the cable cabinet. The processor connected to the connection module may receive, via the universal serial bus interface, a cable control instruction transmitted in a wired transmission mode by a terminal, and control, according to the cable control instruction, the connection module for a target cable corresponding to the cable control instruction, so as to control on/off of the target cable. In this way, the on/off of the target cable can be automatically controlled by means of the cable control instruction, which achieves a purpose of remotely controlling the on/off of the cables. Moreover, the entire process requires no manual operation, thereby preventing the shortcomings of lower cable control safety due to potential hazards caused by manual operation, thereby improving the cable control safety.

### BRIEF DESCRIPTION OF THE DRAWINGS

In order to more clearly illustrate the technical solutions in embodiments of the present disclosure or the related technology, the accompanying drawings used in the description of the embodiments or the related technology are briefly introduced below. It is apparent that, the accompanying drawings in the following description are only some embodiments of the present disclosure, and other drawings can be obtained by those of ordinary skill in the art from the provided drawings without creative efforts.

FIG. 1 is a structural block diagram of a cable control system according to an embodiment;

FIG. 2 is a structural block diagram of a cable indicator light according to an embodiment; and

FIG. 3 is a structural block diagram of a processor indicator light according to an embodiment.

### DETAILED DESCRIPTION

To make the objectives, technical solutions, and advantages of the present disclosure more comprehensible, the present disclosure is described in further detail below according to embodiments with reference to the accompanying drawings. It should be understood that specific embodiments described herein are merely illustrative for the present disclosure and are not intended to limit the present disclosure.

It should be noted that user information (including, but not limited to, user device information and user personal information) and data (including, but not limited to, data for analysis, stored data, and displayed data) as referred to in the present disclosure are all information and data authorized by users or fully authorized by all parties, and the collection, use and processing of relevant data need to comply with relevant regulations.

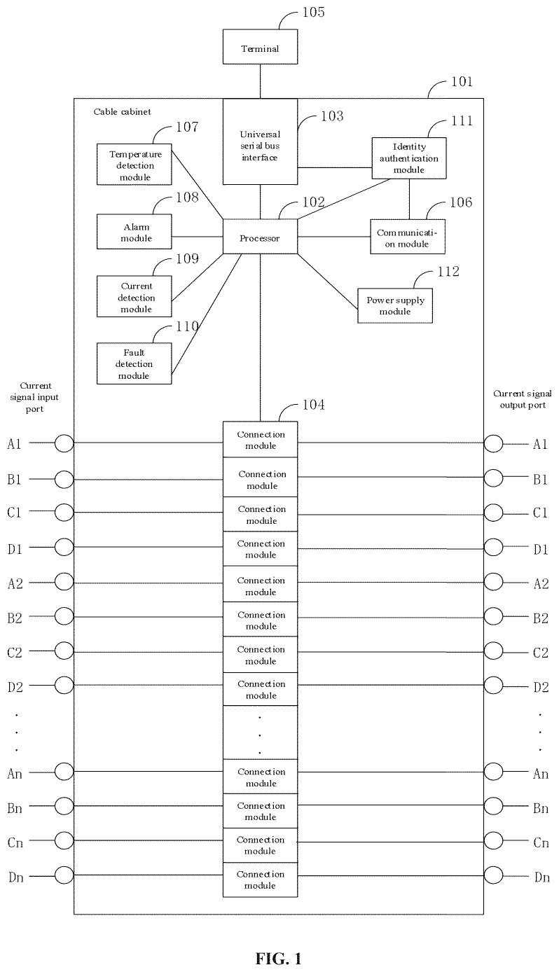

In an exemplary embodiment, as shown in FIG. 1, a cable control system is provided. The system includes a cable cabinet 101, a processor 102 arranged inside the cable cabinet 101, and a universal serial bus interface 103 which is arranged outside the cable cabinet 101 and connected to the processor 102. Cable ports of multiple cable circuits are further arranged outside the cable cabinet 101. Cable ports of each cable circuit include current signal input ports and current signal output ports of multiple cables. The current signal input port and the current signal output port of each cable are connected via a connection module 104 arranged inside the cable cabinet 101. The connection module 104 is further connected to the processor 102. The processor 102 is configured for receiving, via the universal serial bus interface 103, a cable control instruction transmitted in a wired transmission mode by a terminal 105, and for controlling, according to the cable control instruction, the connection module 104 for a target cable corresponding to the cable control instruction, so as to control on/off of the target cable.

It should be noted that configuration of the cables may be represented in the following manner. As shown in FIG. 1, A1, B1, C1, and N1 denote one cable circuit, while A2, B2, C2, and N2 denote another cable circuit. Moreover, A, B, and C denote three-phase lines, and N denotes a neutral line.

The cable cabinet 101 is a device configured for providing centralized management and protection for cables, whose size is adjustable according to actual situations.

The processor 102 is a device configured for controlling on/off of the cables, for example, a central processing unit (CPU). Certainly, the processor 102 may alternatively be any processor chip on the market.

The universal serial bus interface 103 may be a universal serial bus (USB) interface.

The cable port refers to a cable connection interface.

The current signal input port refers to a cable port configured for receiving a current signal, and is connected to a control end via an external input cable. The control end may refer to a control instrument or a control terminal.

The current signal may refer to an electrical signal transmitted through the cable.

The current signal output port refers to a cable port configured for outputting a current signal, and is connected to an end under test via an external output cable. The end under test may refer to a power device under test.

The connection module 104 refers to a cable connector connecting the current signal input port and the current signal output port of the cable. Specifically, the connection module 104 refers to an electric switch or intelligent switch that can be connected to a network. In a case where the cable control instruction is a cable on instruction, the electric switch or intelligent switch is automatically switched on according to the cable on instruction, causing the current signal input port and the current signal output port to be connected. In a case where the cable control instruction is a cable off instruction, the electric switch or intelligent switch is automatically switched off according to the cable off instruction, causing the current signal input port and the current signal output port to be disconnected.

The terminal 105 may be, but is not limited to, various personal computers, laptop computers, smartphones, and tablet computers.

The wired transmission mode refers to a mode in which the cable control instruction is transmitted by means of a data cable (such as a USB data cable).

The cable control instruction refers to an instruction related to control over on/off of a cable, including the cable on instruction and the cable off instruction, which is configured for indicating which cable in which cable circuit is to be controlled, for example, cable A1.

The target cable refers to a cable corresponding to the cable control instruction, that is, a cable to which the cable control instruction is specific.

For example, the terminal 105 generates a cable control instruction in response to a user operation, and sends the cable control instruction to the processor 102 through a data cable between the terminal 105 and the universal serial bus interface 103. The processor 102 receives, via the universal serial bus interface 103, the cable control instruction transmitted in a wired transmission mode by the terminal 105, and selects, according to the cable control instruction, a cable corresponding to a cable identifier (e.g., a cable serial number) carried in the cable control instruction as the target cable from the cables in the cable cabinet. Subsequently, the processor 102 controls the connection module 104 for the target cable corresponding to the cable control instruction, to control on/off of the target cable, for example, turn off the target cable or turn on the target table.

In the embodiment, the on/off of the target cable can be automatically controlled by means of the cable control instruction, and the entire process requires no manual operation, thereby preventing the shortcomings of lower cable control safety due to potential hazards caused by manual operation, thereby improving the cable control safety. Moreover, by means of the system, the on/off of the cables can be remotely operated, which eliminates a need for on-site manual operation, thereby improving cable operation efficiency. Meanwhile, by means of the cable control instruction, on/off of the corresponding cables can be precisely operated, thereby improving cable operation accuracy.

In an exemplary embodiment, as shown in FIG. 1, the cable control system further includes a communication module 106 connected to the processor 102. The communication module 106 is configured for receiving a cable control instruction transmitted in a wireless transmission mode by the terminal 105, and sending the cable control instruction to the processor 102.

The communication module 106 includes a Bluetooth communication module, a wireless communication technology (WiFi) communication module, a 4G communication module, a 5G communication module, or a global system for mobile communication (GSM) communication module.

The wireless transmission mode refers to a mode in which the cable control instruction is transmitted by means of a network, Bluetooth, or WiFi.

For example, the terminal 105 generates a cable control instruction and transmits the cable control instruction to the communication module 106 in the wireless transmission mode. The communication module 106 receives the cable control instruction transmitted in the wireless transmission mode by the terminal 105, and sends the cable control instruction to the processor 102.

In the embodiment, by means of the wireless transmission mode, limitations of physical connections are effectively eliminated, so that the terminal 105 can send the cable control instruction without any physical connection, which helps to improve flexibility and convenience of transmission of the cable control instruction.

In an exemplary embodiment, as shown in FIG. 1, the communication module 106 is further configured for receiving an on/off state of each cable in each cable circuit acquired by the processor 102, and sending the on/off state of each cable in each cable circuit to the terminal 105, to enable the terminal 105 to display the on/off state of each cable in each cable circuit.

The on/off state refers to a state indicating whether a current can flow normally in a cable, including a cable on state and a cable off state.

For example, the processor 102 acquires an on/off state of each cable in each cable circuit, and sends the on/off state of each cable in each cable circuit to the communication module 106. The communication module 106 receives the on/off state of each cable in each cable circuit acquired by the processor 102 and sends the on/off state of each cable in each cable circuit to the terminal 105. The terminal 105 receives the on/off state of each cable in each cable circuit, and displays the on/off state of each cable in each cable circuit. For example, a collected signal or collected data is transmitted to a remote terminal (such as a mobile phone or computer) for visualized display or processing.

In the embodiment, the on/off state of each cable in each cable circuit is sent to the terminal through the communication module 106, which facilitates real-time display of an operating state of the cable, and enables timely detection of cable faults or abnormalities, so as to take corresponding maintenance or repair measures, thereby preventing the shortcomings of missed determination or mis-determination caused by manual determination on the operating state of the cable.

In an exemplary embodiment, as shown in FIG. 1, the cable control system further includes a temperature detection module 107 and an alarm module 108 that are connected to the processor 102. The temperature detection module 107 is configured for detecting a temperature of each cable in a same cable circuit and sending the temperature of each cable in the same cable circuit to the processor 102. The processor 102 is further configured for confirming, in a case where differences between a temperature of a cable and temperatures of other cables in the same cable circuit are greater than a preset threshold, that the cable has a fault, triggering the alarm module 108 to alarm, and sending fault information of the cable to the terminal 105 through the communication module 106.

The temperature detection module 107 is a temperature sensor that is common on the market and configured for detecting a surface temperature of the cable, typically including a thermocouple, a thermal resistor, an infrared sensor, and the like.

The alarm module 108 is an alarm device that is common on the market and configured for alarming, typically including a voice alarm, a visual alarm, an audible and visual alarm, and the like

The preset threshold refers to a threshold set in advance and is configured for determining differences between a temperature of a cable and temperatures of other cables. In a case where there exists a cable, the differences between the temperature of the cable and the temperatures of other cables in the same cable circuit as the cable being greater than the preset threshold, it is confirmed that the cable has a fault. Otherwise, it is confirmed that no cable has fault.

The fault information refers to information corresponding to the cable that has a fault.

For example, the temperature detection module 107 detects a temperature of each cable in a same cable circuit and sends the temperature of each cable in the same cable circuit to the processor 102. The processor 102 receives the temperature of each cable in the same cable circuit, calculates differences between the temperature of one cable and the temperatures of other cables in the same cable circuit, and makes determination on the differences. In a case where the differences between the temperature of the cable and the temperatures of the other cables in the same cable circuit are all greater than the preset threshold, the processor 102 confirms that the cable has a fault, triggers the alarm module 108 to alarm, and sends fault information of the cable to the terminal 105 through the communication module 106, to enable the terminal 105 to display the fault information of the cable. For example, referring to FIG. 1, if a temperature difference between cable A1 and cable B1, a temperature difference between cable A1 and cable C1, and a temperature difference between cable A1 and cable N1 are all greater than the preset threshold, it indicates that cable A1 has a fault.

In the embodiment, by comparing and determining the temperatures of respective cables, an alarm is triggered and corresponding fault information is generated in the case where differences between the temperature of a cable and the temperatures of other cables are greater than the preset threshold, which facilitates rapid confirmation of the faulty cable, thereby improving accuracy and timeliness of cable fault detection.

In an exemplary embodiment, as shown in FIG. 1, the cable control system further includes a current detection module 109 connected to the processor 102. The current detection module 109 is configured for detecting current information at two ends of each cable in a same cable circuit and sending the current information at the two ends of each cable in the same cable circuit to the processor 102. The processor 102 is further configured for sending the current information at the two ends of each cable in the same cable circuit to the terminal 105 through the communication module 106.

The current detection module 109 is a current sensor that is common on the market and is configured for detecting a current, for example, a Hall current sensor.

The current information may refer to magnitude of a current flowing through the cable.

For example, the current detection module 109 detects current information at two ends of each cable in a same cable circuit and sends the current information at the two ends of each cable in the same cable circuit to the processor 102. The processor 102 receives the current information at the two ends of each cable in the same cable circuit, and sends the current information at the two ends of each cable in the same cable circuit to the terminal 105 through the communication module 106, to enable the terminal 105 to display the current information at the two ends of each cable in the same cable circuit.

Further, the processor 102 receives current information of each cable in a same cable circuit, and makes determination on the current information. In a case where the current information meets a preset condition (e.g., a current value of the current flowing through the cable is greater than a preset current value), the processor 102 confirms that the cable corresponding to the current information has a fault, triggers the alarm module 108 to alarm, and sends fault information of the cable to the terminal 105 through the communication module 106, to enable the terminal 105 to display the fault information of the cable.

In the embodiment, by detecting the current information at the two ends of each cable in a same cable circuit in real time and sending the current information at the two ends of each cable to the terminal through the communication module, staff can easily understand the condition of the current of the cable, thereby improving maintenance efficiency and management level of the cable.

In an exemplary embodiment, as shown in FIG. 1, the cable control system further includes a fault detection module 110 connected to the processor 102. The fault detection module 110 is configured for detecting whether each cable in each cable circuit has a fault and sending a fault state of each cable in each cable circuit to the processor 102. The processor 102 is further configured for sending the fault state of each cable in each cable circuit to the terminal 105 through the communication module 106.

The fault detection module 110 is a device that is common on the market and configured for detecting a cable fault, for example, a cable fault tester.

The fault state is configured for indicating fault information corresponding to the cable.

For example, the fault detection module 110 detects whether each cable in each cable circuit has a fault and sends a fault state of each cable in each cable circuit to the processor 102. The processor 102 receives the fault state of each cable in each cable circuit, and sends the fault state of each cable in each cable circuit to the terminal 105 through the communication module 106, enabling the terminal 105 to display the fault state of each cable in each cable circuit.

In the embodiment, by detecting, in real time, whether each cable in each cable circuit has a fault and sending a fault state of each cable in each cable circuit to the terminal through the communication module, the staff can easily understand a fault condition of the cable, thereby helping to improve accuracy and timeliness of cable fault detection and reducing a probability of fault occurrence.

In an exemplary embodiment, as shown in FIG. 1, the cable control system further includes an identity authentication module 111 connected to each of the universal serial bus interface 103, the communication module 106, and the processor 102. The identity authentication module 111 is configured for verifying identity information carried in the cable control instruction received through the universal serial bus interface 103 or the communication module 106, and sending the cable control instruction to the processor 102 in a case where the identity information passes the verification.

The identity authentication module 111 is a module that is common on the market and configured for verifying identity, such as a fingerprint recognition module, a face recognition module, or a voiceprint recognition module.

For example, the universal serial bus interface 103 receives the cable control instruction carrying the identity information such as a fingerprint, a face, or a voiceprint, and sends the cable control instruction carrying the identity information to the identity authentication module 111. The identity authentication module 111 verifies the identity information carried in the cable control instruction received through the universal serial bus interface 103, and sends the cable control instruction to the processor 102 in the case where the identity information passes the verification. For example, if the identity information matches preset identity information, it is confirmed that the identity information passes the verification.

Further, the communication module 106 receives the cable control instruction carrying the identity information, and sends the cable control instruction carrying the identity information to the identity authentication module 111. The identity authentication module 111 verifies the identity information carried in the cable control instruction received through the communication module 106, and sends the cable control instruction to the processor 102 in a case where the identity information passes the verification.

In the embodiment, receiving the cable control instruction through the universal serial bus interface or the communication module helps to improve flexibility of transmission of the cable control instruction. Moreover, verifying the identity information carried in the received cable control instruction ensures that only authorized users can send the cable control instruction, which helps to improve safety of execution of the cable control instruction, thereby improving the cable control safety.

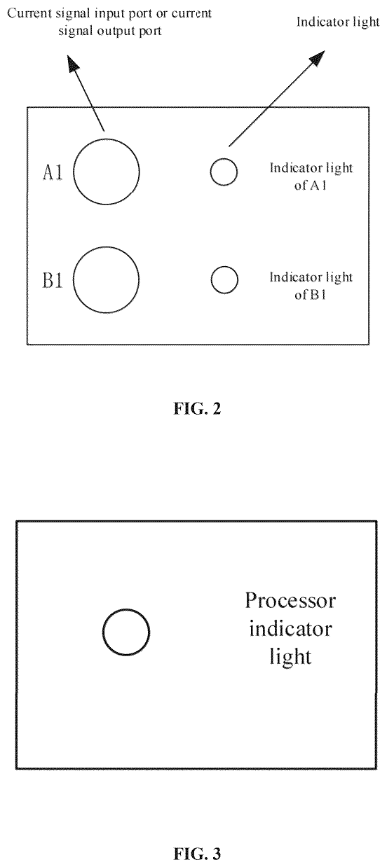

In an exemplary embodiment, as shown in FIG. 2, a corresponding cable indicator light is arranged near the current signal input port or the current signal output port of each cable, and the cable indicator light is configured for indicating an on/off state and a fault state of the corresponding cable.

The cable indicator light refers to an indicator light configured for indicating an on/off state and a fault state of the corresponding cable, which may refer to a light emitting diode (LED) indicator light.

For example, the cable indicator light displays, according to a state of the cable, light in a color corresponding to the state of the cable.

For example, referring to FIG. 2, when the cable A1 is in the on state, an indicator light of the cable A1 displays green light. When the cable A1 is in the off state, the indicator light of the cable A1 displays red light. When the cable A1 is in the fault state, the indicator light of the cable A1 displays blue light.

In the embodiment, the on/off state and the fault state of the corresponding cable can be understood intuitively by means of the cable indicator light, facilitating the user to quickly determine an operating condition of the cable. Moreover, different states of the cable can be indicated more intuitively by means of colors of the indicator light, facilitating rapid recognition by the user.

In an exemplary embodiment, as shown in FIG. 3, a processor indicator light corresponding to the processor is further arranged outside the cable cabinet, and the processor indicator light is configured for indicating a power supply state, an operating state, and a fault state of the processor 102.

The processor indicator light refers to an indicator light configured for indicating the power supply state, the operating state, and the fault state of the processor 102, which may refer to an LED indicator light.

For example, the processor indicator light displays, according to a state of the processor 102, light in a color corresponding to the state of the processor 102.

For example, referring to FIG. 3, when the processor 102 is in the power supply state, the processor indicator light displays yellow light. When the processor 102 is in the operating state, the processor indicator light displays green light. When the processor 102 is in the fault state, the processor indicator light displays red light.

In the embodiment, the power supply state, the operating state, and the fault state of the processor 102 can be understood intuitively by means of the processor indicator light, facilitating the user to quickly determine an operating condition of the processor 102, and facilitating timely recognition of abnormalities, thereby ensuring stable operation of the device.

In an exemplary embodiment, as shown in FIG. 1, the cable control system further includes a power supply module 112 connected to the processor 102. The power supply module 112 is configured for supplying power to the processor 102.

The power supply module 112 is typically a power supply module common on the market, including a regulated power supply, a switching power supply, and the like.

In the embodiment, a stable power supply is provided to the running processor 102 by means of the power supply module 112 connected to the processor 102, thereby improving endurance and stability of the cable control system.

In an exemplary embodiment, to more clearly illustrate the cable control system provided in the embodiments of the present disclosure, the cable control system is specifically described below with a specific embodiment. In an embodiment, as shown in FIG. 1, the present disclosure further provides a cable control system. The system is provided with a cable cabinet, a processor arranged inside the cable cabinet, and a universal serial bus interface that is arranged on outside the cable cabinet and connected to the processor. Cable ports of multiple cable circuits are further arranged outside the cable cabinet. Cable ports of each cable circuit include current signal input ports and current signal output ports of multiple cables, and the current signal input port and the current signal output port of each cable are connected via a connection module arranged inside the cable cabinet. The processor connected to the connection module may receive, through the universal serial bus interface, a cable control instruction transmitted in a wired transmission mode by a terminal, and control, according to the cable control instruction, the connection module for a target cable corresponding to the cable control instruction, so as to control on/off of the target cable, thereby improving the cable control safety. It is specifically detailed with following contents.

(1) Multiple cable circuits are arranged inside the cable control system. Each cable circuit includes input ports and output ports of Line A, Line B, Line C (three-phase lines), and Line N (neutral line), and the input ports and the output ports are in one-to-one correspondence. A USB interface is arranged outside; hence, a cable control program transmitted from a computer can be received through a USB data cable and then transmitted to the processor arranged inside the cable control system. The processor controls on/off of a corresponding cable (e.g., cable A1) in a corresponding cable circuit according to the received cable control program.

(1) A temperature detection unit is arranged inside, which can detect temperatures of different cables in a same cable circuit. Under normal conditions, the temperatures of different cables are relatively close. If the temperature of one cable is higher than temperatures of other cables, it means that the cable has a fault.

(3) A current detection unit is arranged inside and is configured for detecting currents at two ends of a same cable. Alternatively, detection holes may be arranged near the input port and the output port, to be connected with an external current detection unit to perform current detection.

(4) A communication unit is arranged inside and is configured for transmitting a collected signal or collected data to a remote terminal (such as a mobile phone or computer) for visualized display or processing. For example, on/off of each cable in each cable circuit is displayed to perform remote monitoring. Alternatively, the communication unit receives a control instruction transmitted by the remote terminal, and performs a related control operation such as controlling on/off of a corresponding cable (e.g., cable A1) of a corresponding cable circuit, achieving remote control.

(5) A fault diagnosis unit is arranged inside and is configured for detecting whether a cable has a fault.

(6) Each cable circuit has a corresponding indicator light to identify an on state, an off state, and a fault state of the cable.

(7) The processor has a corresponding indicator light to identify a power supply state, an operating state, and a fault state of the processor.

(8) An identity authentication unit is arranged outside. Independent and unique identity authentication is required before utilizing the cable control system.

In the above embodiments, the on/off of the target cable can be automatically controlled by means of the cable control instruction, and the entire process requires no manual operation, thereby preventing the shortcomings of lower cable control safety due to potential hazards caused by manual operation, thereby improving the cable control safety. Moreover, by means of the system, the on/off of the cables can be remotely operated, which eliminates a need for on-site manual operation, thereby improving cable operation efficiency. Meanwhile, by means of the cable control instruction, on/off of the corresponding cables can be precisely operated, thereby improving cable operation accuracy.

The technical features in the above embodiments may be randomly combined. For concise description, not all possible combinations of the technical features in the above embodiments are described. However, all the combinations of the technical features are to be considered as falling within the scope described in this specification provided that they do not conflict with each other.

The above embodiments only describe several implementations of the present disclosure, and their description is specific and detailed, but cannot therefore be understood as a limitation on the patent scope of the present disclosure. It should be noted that those of ordinary skill in the art may further make variations and improvements without departing from the conception of the present disclosure, and these all fall within the protection scope of the present disclosure. Therefore, the protection scope of the present disclosure should be subject to the appended claims.

1. A cable control system, comprising: a cable cabinet, a processor arranged inside the cable cabinet, and a universal serial bus interface that is arranged outside the cable cabinet and connected to the processor; wherein
cable ports of a plurality of cable circuits are further arranged outside the cable cabinet, the cable ports of each cable circuit comprise current signal input ports and current signal output ports of a plurality of cables, and the current signal input port and the current signal output port of each cable are connected via a connection module arranged inside the cable cabinet, the connection module being further connected to the processor; and
the processor is configured to: receive, via the universal serial bus interface, a cable control instruction transmitted in a wired transmission mode by a terminal, and control, according to the cable control instruction, the connection module for a target cable corresponding to the cable control instruction, to control on/off of the target cable, the cable control instruction comprising a cable on instruction and a cable off instruction;
wherein the cable control system further comprises a communication module connected to the processor; and
the communication module is configured to: receive the cable control instruction transmitted in the wireless transmission mode by the terminal, and send the cable control instruction to the processor;
wherein the cable control system further comprises a temperature detection module and an alarm module that are connected to the processor;
the temperature detection module is configured to: detect a temperature of each cable in a same cable circuit and send the temperature of each cable in the same cable circuit to the processor; and
the processor is further configured to: confirm, in a case where differences between the temperature of a cable and the temperatures of other cables in the same cable circuit are greater than a preset threshold, that the cable has a fault, trigger the alarm module to alarm, and send fault information of the cable to the terminal through the communication module.

2. The cable control system according to claim 1, wherein the cable cabinet is a device configured for providing centralized management and protection for cables.

3. The cable control system according to claim 1, wherein the communication module is further configured to: receive an on/off state of each cable in each cable circuit acquired by the processor, and transmit the on/off state of each cable in each cable circuit to the terminal, to enable the terminal to display the on/off state of each cable in each cable circuit.

4. The cable control system according to claim 1, wherein the communication module comprises a Bluetooth communication module, a WiFi communication module, a 4G communication module, a 5G communication module, or a global system for mobile communication (GSM) communication module.

5. The cable control system according to claim 1, further comprising a current detection module connected to the processor; wherein
the current detection module is configured to: detect current information at two ends of each cable in a same cable circuit and send the current information at the two ends of each cable in the same cable circuit to the processor; and
the processor is further configured to send, through the communication module, the current information at the two ends of each cable in the same cable circuit to the terminal.

6. The cable control system according to claim 1, further comprising a fault detection module connected to the processor; wherein
the fault detection module is configured to: detect whether each cable in each cable circuit has a fault, and send a fault state of each cable in each cable circuit to the processor; and
the processor is further configured to send, through the communication module, the fault state of each cable in each cable circuit to the terminal.

7. The cable control system according to claim 1, further comprising an identity authentication module which is connected to each of the universal serial bus interface, the communication module, and the processor; wherein
the identity authentication module is configured to: verify identity information carried in the cable control instruction received through the universal serial bus interface or through the communication module, and send the cable control instruction to the processor in a case where the identity information passes verification.

8. The cable control system according to claim 1, wherein a corresponding cable indicator light is arranged near the current signal input port or the current signal output port of each cable, the cable indicator light being configured to indicate an on/off state and a fault state of the corresponding cable.

9. The cable control system according to claim 1, wherein a processor indicator light corresponding to the processor is further arranged outside the cable cabinet, the processor indicator light being configured to indicate a power supply state, an operating state, and a fault state of the processor.

10. The cable control system according to claim 1, further comprising a power supply module connected to the processor; wherein
the power supply module is configured to supply power to the processor.
